(19) United States
(12) Patent Application Publication
(10) Pub. No.: US 2013/0193451 A1
(43) Pub. Date: Aug. 1, 2013

(54) Photo-Coupler

(71) Applicant: Chao-Hsuan Su, New Taipei City (TW)

(72) Inventor: Chao-Hsuan Su, New Taipei City (TW)

(21) Appl. No.: 13/511,398

(22) PCT Filed: Nov. 23, 2010
(86) PCT No.: PCT/CN2010/079014

§ 371 Date: Jul. 20, 2012

(30) Foreign Application Priority Data
Nov. 23, 2009 (CN) 200910224984.0

(51) Int. Cl. H01L 33/48

(52) U.S. Cl. CPC H01L 33/48
USPC 257/84

(57) ABSTRACT

A photo-coupler is provided. The photo-coupler comprises a plurality of photo-coupling modules, a third package, a power lead and a ground lead. Each of the photo-coupling modules includes a light emitting component, a photosensitive component, a first transparent package and a second transparent package. In each of the photo-coupler modules, the photosensitive component is disposed opposite the light emitting component for receiving the light emitted by the light emitting component. In addition, the first transparent package encloses the light emitting component, while the second transparent package encloses the light emitting component and the first transparent package. The third package encloses both of the second transparent packages to block light from the outside. The photosensitive components electrically connect to the common power lead respectively and electrically connect to the common ground lead respectively inside the third package.

### FIELD OF THE INVENTION

The present invention relates to a photo-coupler; more specifically, the present invention relates a multi-channel photo-coupler.

### DESCRIPTIONS OF THE RELATED ART

Photo-couplers are mediums for electric signal transmission by transforming a light signal into an electric signal, and vice versa. The photo-coupler employs a light emitting component to transform an input electric signal into a light signal, which is then received by a photosensitive component to be transformed back into the electric signal for output, and if necessary, the output may even be regulated. Because photo-couplers transmit electric signals via light, they deliver superior effects of circuit isolation, electrical insulation, circuit protection, interference immunity, etc, therefore, are widely used in various kinds of circuits.

It is common to use multiple photo-couplers simultaneously in a circuit. However, when multiple photo-couplers are used together, the primary concern is that a large number of leads may result in an over large volume. FIG. 1A illustrates the top view of a photo-coupler 1. When a single conventional photo-coupler 1 is used, three leads must be provided on the output side (i.e., the photosensitive end), namely, a power lead (Vcc) 11, an output lead (Vout) 12 and a ground lead (GND) 13. Therefore, if two photo-couplers 1 are to be used together, there will be six leads altogether at the output side, which will add to the complexity in the circuit design. Moreover, the use of multiple photo-couplers 1 together will require a considerable area and a circuit layout on a circuit board for use to arrange these photo-couplers 1, which causes the occupied area on the circuit board to increase in proportion to the number of photo-couplers 1.

FIG. 1B shows a schematic cross-sectional side view of the photo-coupler 1. In the manufacturing process of a conventional photo-coupler 1, silicone 14 is directly applied between a light emitting component 15 and a photosensitive component 16, and then an outer molded plastic 17 is used to block interference from the ambient light. However, in the process of manufacturing the photo-coupler 1, the amount of silicone needed is relatively large, because the silicone 14 must cover both the light emitting component 15 and the photosensitive component 16, making the stability of applying the silicone more difficult to control. Consequently, conditions, such as insufficient coverage of both the light emitting component 15 and the photosensitive component 16 or the overflow of silicone, can lead to further light loss from the light emitting component. This leads to a decrease in the current transformation ratio or even complete failure of the conventional photo-coupler 1 due to insufficient light received by the photosensitive component.

Accordingly, efforts still have to be made to provide a solution that can decrease the volume and lower the cost when multiple photo-couplers are used together and, meanwhile, improve the yield of the manufacturing process and the light transformation efficiency.

### SUMMARY OF THE INVENTION

To solve the aforesaid problem, an objective of the present invention is to provide a photo-coupler which can decrease the volume when multiple photo-couplers are used together, while improving the yield of the manufacturing process and the light transformation efficiency.

To achieve the aforesaid objective, a photo-coupler is provided in the present invention. The photo-coupler comprises a plurality of photo-coupling modules, a third package, a power lead and a ground lead. Each of the photo-coupling modules comprises a light emitting component, a photosensitive component, a first transparent package and a second transparent package. The light emitting component is adapted to emit a light; the photosensitive component is disposed opposite the light emitting component for receiving the light emitted by the light emitting component; the first transparent package is adapted to enclose the light emitting component; and the second transparent package is adapted to enclose the photosensitive component and the first transparent package. The third package is adapted to enclose the second transparent packages of the photo-coupling modules for blocking light from outside. The photosensitive components are electrically connected to the common power lead respectively and electrically connected to the common ground lead respectively by means of a circuit design inside the third package.

According to the above description, the present invention allows a plurality of photo-coupling modules to share a power lead and a ground lead to reduce the number of leads of the photo-couplers, thereby decreasing the overall volume and lowering the cost. Furthermore, by using the structure of multiple layers of packages, it is unnecessary to use silicone to enclose the light emitting component and the photosensitive component simultaneously, so the yield of the manufacturing process and the light conversion efficiency are significantly improved.

### BRIEF DESCRIPTION OF THE DRAWINGS

The specific feature and the efficiency of the present invention will be further described in the following embodiments and drawings.

FIG. 1A is a top view of a conventional photo-coupler;

FIG. 1B is a schematic cross-sectional side view of the conventional photo-coupler;

FIG. 2 is a schematic cross-sectional top view of a photo-coupler of the present invention;

FIG. 3A is a schematic cross-sectional side view taken along line AA′ in FIG. 2;

FIG. 3B is a schematic cross-sectional side view taken along line BB′ in FIG. 2;

FIG. 4A is a schematic circuit diagram of the side of the photo-coupler that comprises the light emitting components; and

FIG. 4B is a schematic circuit diagram of the side of the photo-coupler that comprises the photosensitive components.

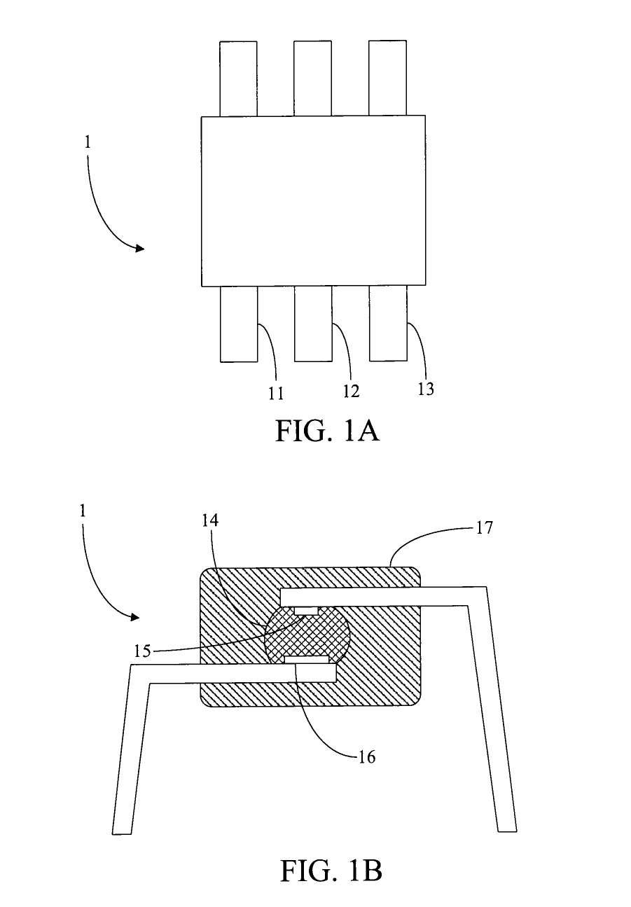

### DESCRIPTION OF THE PREFERRED EMBODIMENT

In the following description, a photo-coupling module of the present invention will be explained with reference to embodiments thereof. However, these embodiments are not intended to limit the present invention to any specific environment, applications or particular implementations described in these embodiments. Therefore, description of these embodiments is only for purposes of illustration rather than limitation.

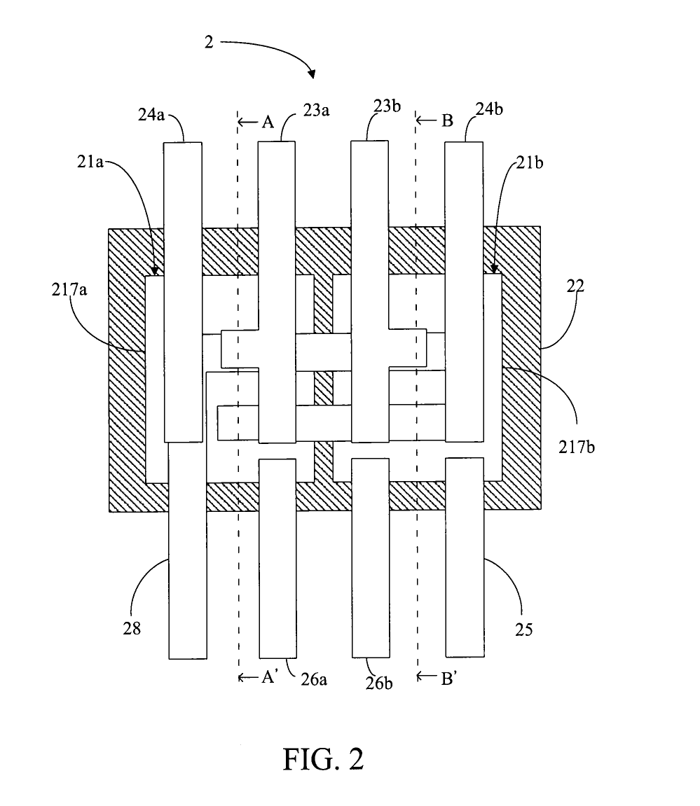

FIG. 2 illustrates a schematic cross-sectional top view of a photo-coupler 2 of the present invention, in which only two second transparent packages 217a, 217b and a third package 22 are shown in cross-section while the remaining portions are not. The photo-coupler 2 of the present invention comprises at least a plurality of photo-coupling modules 21a, 21b, the third package 22, a first input lead 23a, a second input lead 23b, a power lead 25, a first output lead 26a, a second output lead 26b and a ground lead 28. It should be particularly emphasized that there are two photo-coupling modules comprised in the photo-coupler 2 but the number is not limited thereto.

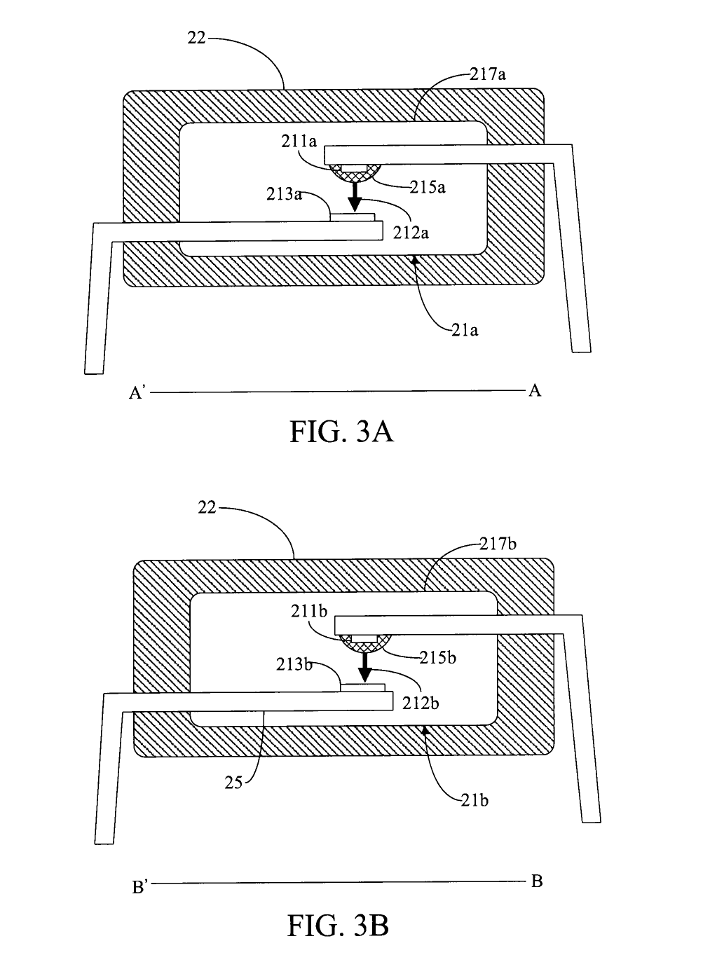

Next, in reference to both FIGS. 3A and FIG. 3B, FIG. 3A is a schematic cross-sectional side view taken along line AA′ in FIG. 2, while FIG. 3B is a schematic cross-sectional side view taken along line BB′ in FIG. 2. For ease of understanding hereinafter, in FIG. 3A and FIG. 3B, only the second transparent packages 217a, 217b and the third package 22 are shown in cross-section while the remaining portions are not. Each of the photo-coupling modules 21a, 21b comprises a light emitting component 211a, 211b, a photosensitive component 213a, 213b, a first transparent package 215a, 215b and a second transparent package 217a, 217b respectively. It should be noted that the light emitting components 211a, 211b may be infrared light emitting diodes (IR LEDs), and the photosensitive components 213a, 213b may be photo transistors (PTs); however, they are not merely limited thereto, and those skilled in the art may easily replace them with components of the same functionality.

Hereinafter, the photo-coupling module 21a will be described as an example, and the photo-coupling module 21b is just of a similar design. Specifically, after receiving an electric signal, the light emitting component 211a of the photo-coupling module 21a emits a light 212a according to the intensity of the electric signal. The photosensitive component 213a is disposed opposite the light emitting component 211a to receive the light 212a emitted by the light emitting component 211a and then transforms the light 212a into an electric signal for output according to the intensity of the light 212a. Here, to dissipate heat from the light emitting component 211a and protect the light emitting component 211a while also transmitting the light 212a, the first transparent package 215a is used to enclose the light emitting component 211a. It should be appreciated that due to the effects of heat dissipation, protection and light transparency must be achieved simultaneously; the preferred choice for the first transparent package 215a of this embodiment is silicone, although it is not intended to limit the material of the first transparent package 215a.

Unlike the drawbacks of the prior art, in which it was difficult to control the amount of silicone when the silicone was being applied, the present invention does not use the first transparent package 215a to directly enclose both the light emitting component 211a and the photosensitive component 213a, but instead, the first transparent package 215a encloses only the light emitting component 211a. Thus, it becomes relatively easier to control the amount of silicone and an enclosing position when the first transparent package 215a is being applied. Afterwards, the second transparent package 217a is used to enclose both the photosensitive component 213a and the first transparent package 215a simultaneously. Because the second transparent package 217a is made of a transparent material, the light 212a can pass through both the first transparent package 215a and the second transparent package 217a to reach the photosensitive component 213a. The operations and structure of the photo-coupling module 21b are just similar to those of the photo-coupling module 21a and, thus, will not be further described herein.

Finally, the third package 22, which is opaque, is used to enclose both the second transparent package 217a of the photo-coupling module 21a and the second transparent package 217b of the photo-coupling module 21b simultaneously, one purpose of which is to block the light from outside to prevent the photosensitive components 213a and 213b from being influenced. Additionally, because the second transparent package 217a of the photo-coupling module 21a and the second transparent package 217b of the photo-coupling module 21b are disposed separately, the second transparent packages 217a and 217b can also be partitioned when being enclosed by the third package 22. Thus, the photosensitive component 213a of the photo-coupling module 21a and the photosensitive component 213b of the photo-coupling module 21b inside the photo-coupler 2 will not receive light 212a and the light 212b from each other.

It should be noted that the preferred material of the second transparent packages 217a, 217b and the third package 22 is epoxy. Because the third package 22 needs to block the light from outside, the material of the third package 22 also contains carbon black in addition to the epoxy. In this case, although the second transparent packages 217a, 217b and the third package 22 all adopt epoxy as the primary material, the third package 22 also contains the carbon black, which makes the coefficient of thermal expansion of the third package 22 different from those of the second transparent packages 217a, 217b. To avoid deformation of the second transparent packages 217a, 217b and the third package 22 from overheating during operation due to their different coefficients of thermal expansion, SiO₂ may be added to the second transparent packages 217a, 217b appropriately so that the coefficients of the thermal expansion of the second transparent packages 217a, 217b and the third package 22 become closer to each other while still ensuring adequate transparency of the second transparent packages 217a, 217b.

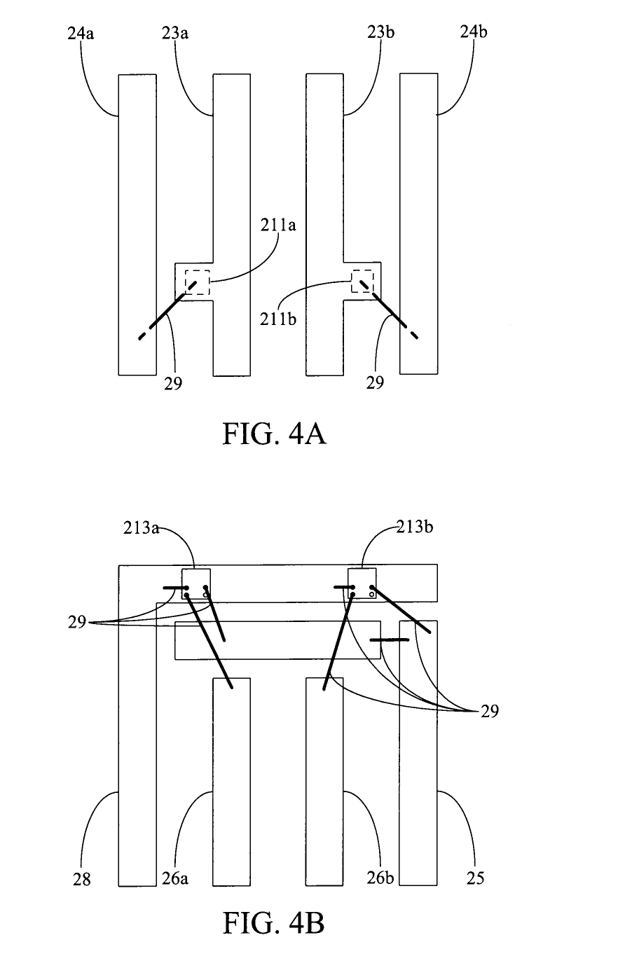

Next, in reference to both FIG. 4A and FIG. 4B, a schematic circuit diagram of the side of the photo-coupler 2 that comprises the light emitting components 211a, 211b and a schematic circuit diagram of the side of the photo-coupler 2 that comprises the photosensitive components 213a, 213b, respectively. Specifically, the first input lead 23a and the second input lead 23b are electrically connected to the light emitting components 211a and 211b respectively, and the lead 24a and the lead 24b are correspondingly electrically connected to the light emitting components 211a and 211b via leads 29 respectively. An electric signal is applied across the first input lead 23a and the lead 24a, while another electric signal is applied across the second input lead 23b and the lead 24b so that these electric signals are inputted into the light emitting components 211a and 211b respectively. After receiving the electric signals, the light emitting components 211a and 211b transform the electric signals into light signals (i.e., the light 212a and the light 212b shown in FIGS. 3A, 3B). After sensing the intensity of the light signals, the photosensitive components 213a and 213b transform the light signals back into electric signals correspondingly and output the electric signals respectively from the first output lead 26a and the second output lead 26b electrically connected thereto via the leads 29. The photosensitive component 213a and the photosensitive component 213b are electrically connected to the common power lead 25 respectively and electrically connected to the common ground lead 28 respectively via the leads 29 inside the third package 22.

In other words, with the aforesaid circuit arrangement, the photo-coupling modules 21a, 21b can share the power lead 25 and the ground lead 28 to reduce the number of leads that would otherwise be needed when each of the photo-coupling modules 21a, 21b requires a power lead 25 and a ground lead 28 individually. It should be emphasized that the circuit connections and the positions of leads illustrated in the above description and all the attached drawings are not intended to limit the present invention, and other examples will readily occur to those of ordinary skill in this field. For example, the lead definitions of the first input lead 23a, the second input lead 23b and the leads 24a, 24b may be mutually exchanged, and by only making corresponding modifications on the circuit, the light emitting components 211a and 211b can still be able to transform electric signals into light signals. Similarly, the lead definitions, locations or shapes of the first output lead 26a, the second output lead 26b, the power lead 25 and the ground lead 28 may also be mutually exchanged or modified, and by simply making modifications on the circuit, the photosensitive components 213a and 213b can still be able to transform the light signals back into the electric signals correspondingly. As will also readily occur to those of ordinary skill in this field, the photo-coupler 2 of the present invention may further comprise three or more photo-coupling modules, and the objective of the present invention can still be achieved by using the third package 22 to enclose all the photo-coupling modules and making corresponding modifications on the circuit design so that the three or more photosensitive components are electrically connected to the common power lead 25 and the common ground lead 28.

In summary, by means of the common power lead 25 and the common ground lead 28, the number of leads required by the photo-coupling modules 21a, 21b of the photo-coupler 2 of the present invention gets reduced, thereby decreasing the volume and lowering the cost. Furthermore, by means of the multiple layers of packages, an application of a large amount of silicone is unnecessary, so the production yield and speed are both improved. Thereby, difficulties from the prior art are effectively overcome.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A photo-coupler, comprising:
a plurality of photo-coupling modules, each of the photo-coupling modules including:
a light emitting component for emitting a light;
a photosensitive component disposed opposite to the light emitting component for receiving the light emitted by the light emitting component;
a first transparent package for enclosing the light emitting component; and
a second transparent package for enclosing the photosensitive component and the first transparent package;
a third package for enclosing the second transparent packages for blocking the light from outside;
a power lead; and
a ground lead;
wherein the photosensitive components electrically connect to the common power lead respectively and electrically connect to the common ground lead respectively inside the third package.

2. The photo-coupler of claim 1, wherein the photo-coupler further comprises a first output lead and a second output lead, and the first output lead and the second output lead electrically connect to the photosensitive components respectively.

3. The photo-coupler of claim 1, wherein the photo-coupler further comprises a first input lead and a second input lead, and the first input lead and the second input lead electrically connect to the light emitting components respectively.

4. The photo-coupler of claim 1, wherein the first transparent packages include silicone.

5. The photo-coupler of claim 1, wherein the second transparent packages and the third package include epoxy.

6. The photo-coupler of claim 4, wherein the second transparent packages include epoxy with SiO₂.

7. The photo-coupler of claim 5, wherein the third transparent package includes epoxy and carbon black.

8. The photo-coupler of claim 1, wherein the photosensitive components are photo transistors.

9. The photo-coupler of claim 1, wherein the light emitting components are infrared light emitting diode.
